(19) United States
(12) Patent Application Publication
(10) Pub. No.: US 2025/0180994 A1
(43) Pub. Date: Jun. 5, 2025

(54) SELECTIVE PHOTORESIST APPLICATION METHOD AND SEMICONDUCTOR PACKAGE MANUFACTURING METHOD USING THE SAME

(71) Applicant: SAMSUNG ELECTRONICS CO., LTD., Suwon-si (KR)

(72) Inventors: Juhyung Lee, Suwon-si (KR); Minwoo Rhee, Suwon-si (KR); Juhyeon Kim, Suwon-si (KR); Sunwoo Park, Suwon-si (KR); Seungdon Lee, Suwon-si (KR); Hyunjin Lee, Suwon-si (KR); Sujie Kang, Suwon-si (KR); Jungwoo Cho, Suwon-si (KR)

(21) Appl. No.: 18/952,671

(22) Filed: Nov. 19, 2024

(30) Foreign Application Priority Data
Nov. 30, 2023 (KR) 10-2023-0171830

(51) Int. Cl. G03F 7/16; H01L 21/308; H01L 23/00; H01L 25/065

(52) U.S. Cl. CPC G03F 7/16; H01L 21/3086; H01L 24/05; H01L 25/0657; H01L 2225/06555

(57) ABSTRACT

A selective photoresist application method and a semiconductor package manufacturing method using the selective photoresist application method, wherein the selective photoresist application method includes measuring positions, sizes, and heights of chips provided on a wafer, generating a position image of the chips, preparing a plurality of application images for application of photoresist based on the position image, and sequentially stacking and applying the photoresist on the wafer according to the plurality of application images by using a dispenser, wherein each of the plurality of application images includes a gradation application area corresponding to the chips and a plurality of line application areas corresponding to the chips.

### CROSS-REFERENCE TO RELATED APPLICATION

This application claims priority under 35 U.S.C. § 119 to Korean Patent Application No. 10-2023-0171830, filed in the Korean Intellectual Property Office on Nov. 30, 2023, the disclosure of which is incorporated by reference herein in its entirety.

### BACKGROUND

A general method of manufacturing a semiconductor package includes forming photoresist by spin coating. The photoresist formed by spin coating may include voids, and the photoresist is formed on the upper surface of a semiconductor substrate.

### SUMMARY

In general, in some aspects, the present disclosure is directed toward a selective photoresist application method and a semiconductor package manufacturing method using the selective photoresist application method, thereby improving the manufacturing yield of semiconductor packages and reducing the number of processes in a semiconductor package manufacturing process to improve the production efficiency of semiconductor packages.

In general, according to some aspects, a selective photoresist application method includes measuring positions, sizes, and heights of chips provided on a wafer, generating a position image of the chips, preparing a plurality of application images for application of photoresist based on the position image, and sequentially stacking and applying the photoresist on the wafer according to the plurality of application images by using a dispenser, such as an inkjet dispenser, wherein each of the plurality of application images includes a gradation application area corresponding to the chips and a plurality of line application areas corresponding to the chips, and the gradation application area is defined as an area having an application density of the photoresist of less than 1, and each of the plurality of line application areas is defined as an area having an application density of the photoresist of 1.

According to some aspects of the present disclosure, a semiconductor package manufacturing method includes preparing a wafer structure including a plurality of first semiconductor chips, wherein each of the plurality of first semiconductor chips includes a first semiconductor substrate, a first wiring structure arranged on the first semiconductor substrate, and a plurality of first front surface connection pads at least partially buried in the first wiring structure, adhering, on the wafer structure, an upper semiconductor chip including a preliminary semiconductor substrate, a plurality of through electrodes buried in the preliminary semiconductor substrate, a second wiring structure arranged on the preliminary semiconductor substrate, and a plurality of second front surface connection pads arranged on the second wiring structure, such that the plurality of first front surface connection pads and the plurality of second front surface connection pads correspond to each other, forming a plurality of coupling pads by coupling the plurality of first front surface connection pads to the plurality of second front surface connection pads, aligning the wafer structure on which the upper semiconductor chip is arranged with a plurality of application images for application of photoresist, sequentially stacking and applying the photoresist on the wafer structure according to the plurality of application images, and forming a second semiconductor substrate by removing a portion of the upper semiconductor chip to expose the plurality of through electrodes, wherein each of the plurality of application images including a gradation application area corresponding to the upper semiconductor chip and a plurality of line application areas corresponding to the upper semiconductor chip, and the gradation application area is defined as an area having an application density of the photoresist of less than 1, and each of the plurality of line application areas is defined as an area having an application density of the photoresist of 1.

According to some aspects of the present disclosure, a selective photoresist application method includes measuring a position, size, and height of a preliminary semiconductor substrate provided on a wafer, generating a position image of the preliminary semiconductor substrate, preparing a plurality of application images for application of photoresist based on the position image, and sequentially stacking and applying the photoresist on the wafer according to the plurality of application images by using an inkjet dispenser, wherein each of the plurality of application images include a gradation application area corresponding to the gradation application area and a plurality of line application areas corresponding to the preliminary semiconductor substrate, the gradation application area is spaced apart from an outer edge of the preliminary semiconductor substrate corresponding to the gradation application area, and the gradation application area surrounds the corresponding preliminary semiconductor substrate, the gradation application area is closer to the preliminary semiconductor substrate than the plurality of line application areas, the plurality of application images include at least four application images and include a first application image and a second application image, a second separation distance, which is a separation distance between a second gradation application area of the second application image and the corresponding preliminary semiconductor substrate, is greater than a first separation distance, which is a separation distance between a first gradation application area of the first application image and the corresponding preliminary semiconductor substrate, one line application area among the plurality of line application areas is arranged outside the gradation application area to extend with the gradation application area, the gradation application area includes a plurality of points, and the plurality of points comprise non-application points and application points, the gradation application area has an application density of the photoresist of about 0.3 to about 0.9, each of the plurality of line application areas has an application density of the photoresist of 1, the application density includes a ratio of an area of the application points to an area of the plurality of points of the photoresist, the plurality of line application areas include a first line application area bundle and a second line application area bundle, the first line application area bundle includes two or more line application areas, the second line application area bundle includes two or more line application areas, a first internal line separation distance, which is a separation distance between the two or more line application areas of the first line application area bundle, is less than a first outer line separation distance, which is a separation distance between the first line application area bundle and the second line application area bundle, the first outer line separation distance is greater than the first internal line separation distance by about 2 to about 4 times, an uppermost surface of the stacked photoresist is in contact with an outer edge of an upper surface of the preliminary semiconductor substrate, the upper surface of the preliminary semiconductor substrate is exposed to the outside, and a plurality of coupling pads are provided between the wafer and the preliminary semiconductor substrate.

### BRIEF DESCRIPTION OF THE DRAWINGS

Example implementations will be more clearly understood from the following detailed description, taken in conjunctions with the accompanying drawings.

FIG. 1 is a flowchart illustrating an example of a selective photoresist application method according to some implementations.

FIG. 2 is a flowchart illustrating an example of a semiconductor package manufacturing method using an example of a selective photoresist application method according to some implementations.

FIG. 3 is a diagram illustrating an example of a selective photoresist application method according to some implementations.

FIG. 4A is a diagram illustrating examples of application images in an example of a selective photoresist application method according to some implementations.

FIG. 4B is a cross-sectional view of an example of a semiconductor package, illustrating an example of a semiconductor package manufacturing method using an example of a selective photoresist application method according to some implementations.

FIGS. 5A and 5B are enlarged views of an example of a second region in a first application image according to some implementations.

FIG. 6A is a diagram illustrating examples of application images in an example of a selective photoresist application method according to some implementations.

FIG. 6B is a cross-sectional view of an example of a semiconductor package, illustrating an example of a semiconductor package manufacturing method using an example of a selective photoresist application method according to some implementations.

FIGS. 7 to 9 are cross-sectional views illustrating an example of a semiconductor package manufacturing method using an example of a selective photoresist application method according to some implementations.

FIG. 10 is a flowchart illustrating an example of a semiconductor package manufacturing method using an example of a selective photoresist application method according to some implementations.

FIGS. 11 to 14 are cross-sectional views illustrating an example of a semiconductor package manufacturing method using an example of a selective photoresist application method according to some implementations

### DETAILED DESCRIPTION

Hereinafter, example implementations will be described in detail with reference to the accompanying drawings. In some implementations, sizes and thicknesses of components in the drawings are arbitrarily illustrated for convenience of explanation.

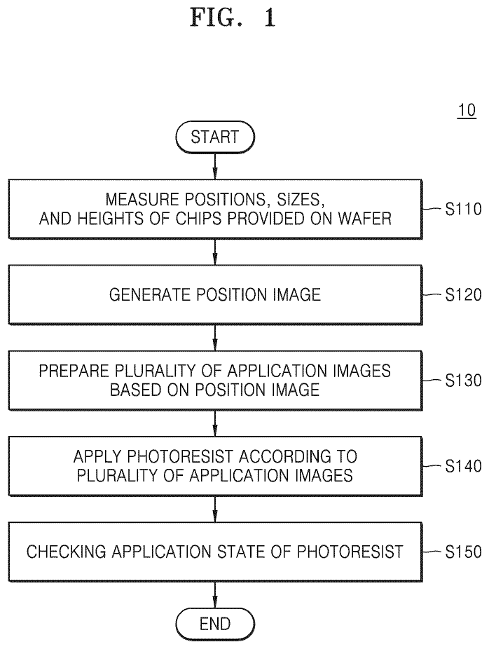

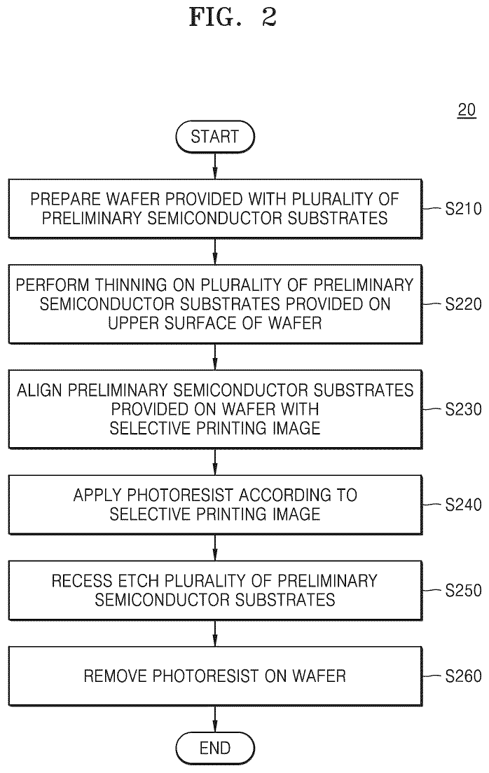

FIG. 1 is a flowchart illustrating an example of a selective photoresist application method according to some implementations. FIG. 2 is a flowchart illustrating an example of a semiconductor package manufacturing method using the selective photoresist application method according to some implementations.

In FIGS. 1 and 2, the selective photoresist application method 10 may include operation S110 of measuring the positions and heights of chips provided on a wafer, operation S120 of generating a position image of the chips, operation S130 of preparing a plurality of application images for application of photoresist based on the position image of the chips, operation S140 of sequentially stacking and applying the photoresist on the wafer according to the plurality of application images by using a photoresist dispenser, and operation S150 of checking an application state of the photoresist. In some implementations, the photoresist dispenser may comprise an inkjet dispenser.

The semiconductor package manufacturing method 20 using the selective photoresist application method 10 may include operation S210 of preparing a wafer structure with a plurality of preliminary semiconductor substrates provided on the upper surface of the wafer structure, operation S220 of thinning the plurality of preliminary semiconductor substrates provided on the upper surface of the wafer structure, operation S230 of aligning the plurality of preliminary semiconductor substrates with a selective printing image, operation S240 of applying photoresist on the wafer structure according to the selective printing image, operation S250 of recess etching the plurality of preliminary semiconductor substrates, and operation S260 of removing the photoresist on the wafer structure. The selective photoresist application method 10 may be included and described in the description of the semiconductor package manufacturing method 20.

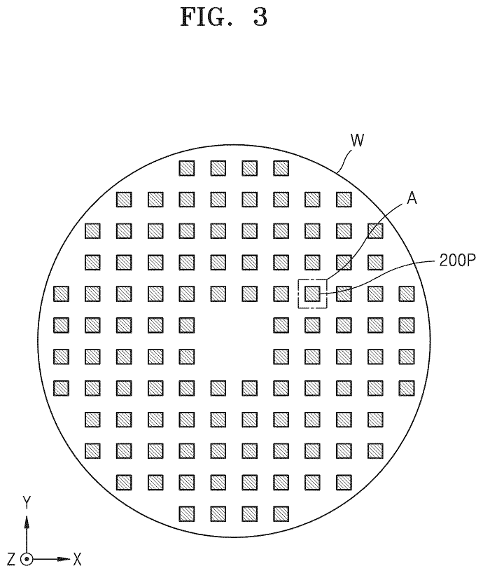

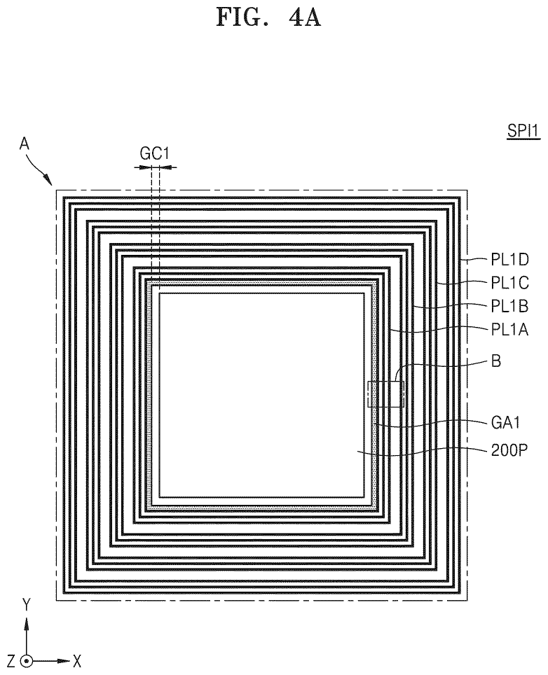

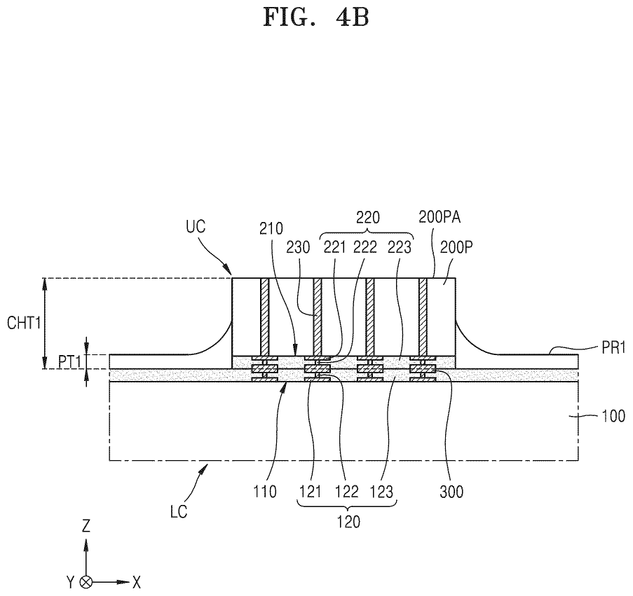

FIG. 3 is a diagram illustrating an example of a selective photoresist application method according to some implementations. FIG. 4A is a diagram illustrating examples of application images in an example of a selective photoresist application method according to some implementations. FIG. 4B is a cross-sectional view of an example of a semiconductor package, illustrating an example of a semiconductor package manufacturing method using an example of a selective photoresist application method according to some implementations.

In FIG. 3, a plurality of preliminary semiconductor substrates 200P may be provided on a wafer W. A plurality of first semiconductor substrates 100, as shown in FIG. 4B, may be included in the wafer W, and corresponding plurality of preliminary semiconductor substrates 200P may be mounted on the plurality of first semiconductor substrates 100.

A photoresist application device or separate measuring equipment may measure the positions and sizes of the plurality of preliminary semiconductor substrates 200P on the wafer W having the plurality of preliminary semiconductor substrates 200P provided on the upper surface thereof, the heights of the plurality of preliminary semiconductor substrates 200P, or the like. A position image of the wafer W including the plurality of preliminary semiconductor substrates 200P may be produced by measuring the measured positions, sizes, and heights of the plurality of preliminary semiconductor substrates 200P.

A photoresist application device may prepare a plurality of application images for application of photoresist, based on the position image of the wafer W. The plurality of application images may be prepared for an entire wafer W or a partial region of the wafer W. A plurality of application images are described with an example of a preliminary semiconductor substrate 200P included in a first portion A of FIG. 3.

In FIG. 4A, a first application image SPI1 among a plurality of application images prepared for the preliminary semiconductor substrate 200P included in the first portion A is shown. The first application image SPI1 is for the first application of photoresist on the wafer W including the plurality of preliminary semiconductor substrates 200P.

A photoresist application device may apply photoresist through a plurality of nozzles. For example, the plurality of nozzles of the photoresist application device may include 1024 nozzles. Whether each of the plurality of nozzles of the photoresist application device applies photoresist may be selected.

Accordingly, as shown in the first application image SPI1 of FIG. 4A, a location to be applied with photoresist and a location not to be applied with photoresist may be selected and designated. The first application image SPI1 may include a first gradation area GA1 and a line application area. The line application area may include, for example, a first line application area bundle PL1A, a second line application area bundle PL1B, a third line application area bundle PL1C, and a fourth line application area bundle PL1D.

Each of the first line application area bundle PL1A, the second line application area bundle PL1B, the third line application area bundle PL1C, and the fourth line application area bundle PL1D may include one or more line application areas. For example, each of the first line application area bundle PL1A, the second line application area bundle PL1B, the third line application area bundle PL1C, and the fourth line application area bundle PL1D may include three line application areas.

The three line application areas included in the first line application area bundle PL1A may be arranged to be spaced apart from each other at a distance. As shown in FIG. 4A, the line application areas may be arranged to be spaced apart from each other with the preliminary semiconductor substrate 200P as the center. Similarly, the three line application areas included in the second line application area bundle PL1B may be arranged to be spaced apart from each other with the preliminary semiconductor substrate 200P as the center, and the three line application areas included in the third line application area bundle PL1C may be arranged to be spaced apart from each other with the preliminary semiconductor substrate 200P as the center. For example, when the preliminary semiconductor substrate 200P has a rectangular shape, each of the line application areas may have a rectangular shape with an enlarged outer edge of the preliminary semiconductor substrate 200P.

The first application image SPI1 may include the first gradation area GA1 between the first line application area bundle PL1A and the outer edge of the preliminary semiconductor substrate 200P. The first gradation area GA1 may have a low photoresist application density, unlike the first line application area bundle PL1A. A photoresist application density of each of the line application areas included in the first line application area bundle PL1A to the fourth line application area bundle PL1D may be 1. Unlike the above description, the first gradation area GA1 may have a photoresist application density of less than 1. The photoresist application density of the first gradation area GA1 may be about 0.3 to about 0.9. For example, the photoresist application density of the first gradation area GA1 may be about 0.5 to about 0.8. Alternatively, the photoresist application density of the first gradation area GA1 may be 0.5.

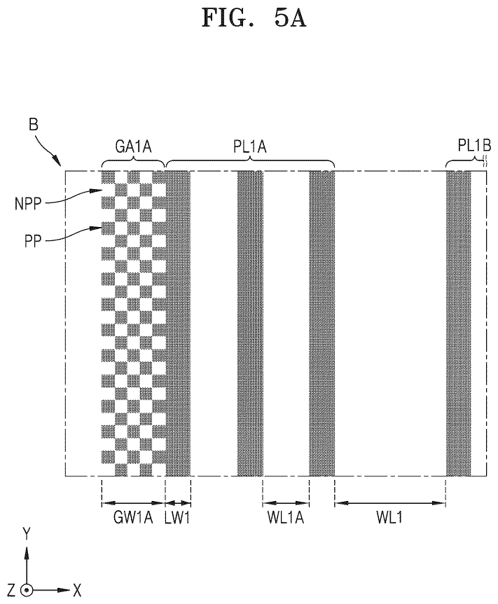

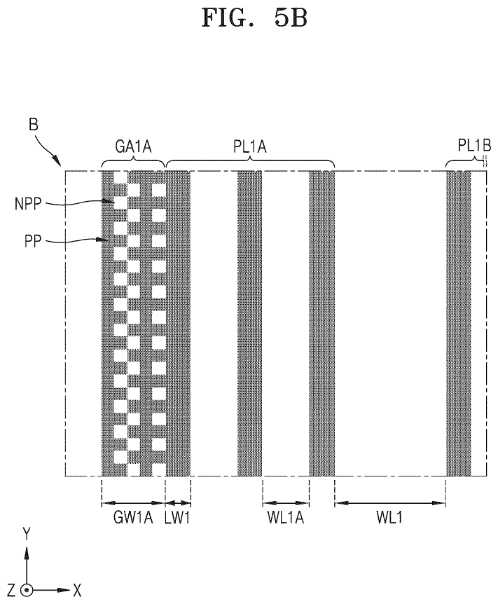

The first gradation area GA1 may be spaced apart from the outer edge of the preliminary semiconductor substrate 200P. In addition, the first gradation area GA1 may surround the outer edge of the preliminary semiconductor substrate 200P. The first gradation area GA1 may be spaced apart from the outer edge of the preliminary semiconductor substrate 200P at a uniform distance. The first gradation area GA1 may be spaced apart from the outer edge of the preliminary semiconductor substrate 200P by a first gap GC1. For example, the first gap GC1 may be about 50 μm to about 200 μm. A detailed description of the first gradation area GA1 is made below with reference to FIGS. 5A and 5B showing an enlarged view of a second area B.

The first line application area bundle PL1A, the second line application area bundle PL1B, the third line application area bundle PL1C, and the fourth line application area bundle PL1D may be arranged to be spaced apart from each other. That is, as shown in FIG. 4A, the second line application area bundle PL1B may be arranged outside the outer edge of the first line application area bundle PL1A and spaced apart from the first line application area bundle PL1A. Similarly, the third line application area bundle PL1C may be arranged outside the second line application area bundle PL1B and spaced apart from the second line application area bundle PL1B. The fourth line application area bundle PL1D may be arranged outside the third line application area bundle PL1C and spaced apart from the third line application area bundle PL1C.

A separation distance between the first line application area bundle PL1A and the second line application area bundle PL1B, a separation distance between the second line application area bundle PL1B and the third line application area bundle PL1C, and a separation distance between the third line application area bundle PL1C and the fourth line application area bundle PL1D may be greater than a separation distance between the line application areas included in the first line application area bundle PL1A. For example, the separation distance between the first line application area bundle PL1A and the second line application area bundle PL1B, the separation distance between the second line application area bundle PL1B and the third line application area bundle PL1C, and the separation distance between the third line application area bundle PL1C and the fourth line application area bundle PL1D may be 1.5 times or more and less than 5 times of the separation distance between the line application areas included in the first line application area bundle PL1A.

In some implementations, unlike the above description, the separation distance between the first line application area bundle PL1A and the second line application area bundle PL1B, the separation distance between the second line application area bundle PL1B and the third line application area bundle PL1C, and the separation distance between the third line application area bundle PL1C and the fourth line application area bundle PL1D may be equal to the separation distance between the line application areas included in the first line application area bundle PL1A. For example, line application areas included in the first line application area bundle PL1A, the second line application area bundle PL1B, the third line application area bundle PL1C, and the fourth line application area bundle PL1D may be arranged at equal distances from each other.

In FIG. 4B, according to the first application image SPI1, a first photoresist layer PR1 may be applied on a first semiconductor substrate 100. The first photoresist layer PR1 may be in contact with a side surface of the preliminary semiconductor substrate 200P and may have a cross-sectional shape in which the thickness of the first photoresist layer PR1 in a vertical direction increases toward the preliminary semiconductor substrate 200P. This is because photoresist tends to adhere to the first semiconductor substrate 100. In the selective photoresist application method 10 according to an embodiment, photoresist is not applied on a first upper surface 200PA, which is the upper surface of the preliminary semiconductor substrate 200P. In addition, as described above, because a gradation application area is arranged in an area adjacent to the preliminary semiconductor substrate 200P, the amount or density of photoresist applied to a position adjacent to the preliminary semiconductor substrate 200P is relatively small, and thus the photoresist may not reach the first upper surface 200PA.

A lower semiconductor chip LC may include the first semiconductor substrate 100 and a first wiring structure 120 arranged on the first semiconductor substrate 100. An upper semiconductor chip UC may include the preliminary semiconductor substrate 200P and a second wiring structure 220 arranged on the preliminary semiconductor substrate 200P. The first wiring structure 120 and the second wiring structure 220 may be respectively referred to as a first back-end-of-line (BEOL) structure and a second BEOL structure.

Each of the first semiconductor substrate 100 and the preliminary semiconductor substrate 200P may include, for example, silicon (Si). Alternatively, each of the first semiconductor substrate 100 and the preliminary semiconductor substrate 200P may include a semiconductor element such as germanium (Ge) or a compound semiconductor such as silicon carbide (SiC), gallium arsenide (GaAs), indium arsenide (InAs), and indium phosphide (InP). Alternatively, each of the first semiconductor substrate 100 and the preliminary semiconductor substrate 200P may include a silicon on insulator (SOI) structure. For example, each of the first semiconductor substrate 100 and the preliminary semiconductor substrate 200P may include a buried oxide (BOX) layer. Each of the first semiconductor substrate 100 and the preliminary semiconductor substrate 200P may include a conductive area, for example, a well doped with impurities or a structure doped with impurities. In addition, each of the first semiconductor substrate 100 and the preliminary semiconductor substrate 200P may have various device isolation structures such as a shallow trench isolation (STI) structure. The first semiconductor substrate 100 may have a first active surface and a first inactive surface opposite to the first active surface of the first semiconductor substrate 100, and similarly, the preliminary semiconductor substrate 200P may include a second active surface and a second inactive surface opposite to the second active surface of the preliminary semiconductor substrate 200P. The first active surface of the first semiconductor substrate 100 and the second active surface of the preliminary semiconductor substrate 200P may face each other.

For example, a first semiconductor device 110 may be arranged on the first active surface of the first semiconductor substrate 100, and the first wiring structure 120 may be arranged on the first active surface of the first semiconductor substrate 100. For example, a second semiconductor device 210 may be arranged on the second active surface of the preliminary semiconductor substrate 200P, and the second wiring structure 220 may be arranged on the second active surface of the preliminary semiconductor substrate 200P.

Herein, unless otherwise described, components including the terms of a front surface and a rear surface respectively refer to a component arranged on an active surface and a component arranged on an inactive surface. In addition, unless otherwise described, the terms of an upper surface and a lower surface (bottom surface) respectively refer to an upper surface and a lower surface in the drawings. For example, in FIG. 4B, the second inactive surface of the preliminary semiconductor substrate 200P may be the first upper surface 200PA, which is the upper surface of the preliminary semiconductor substrate 200P.

In some implementations, the first semiconductor device 110 may be, for example, a memory device, and the second semiconductor device 210 may be, for example, a central processing unit (CPU), a graphics processing unit (GPU), or an application processor (AP). For example, the first semiconductor device 110 may be, for example, a volatile memory device, such as a dynamic random access memory (DRAM) device or a static random access memory (SRAM) device, or a non-volatile memory device, such as a phase-change random access memory (PRAM) device, a magnetoresistive random access memory (MRAM) device, a ferroelectric random access memory (FeRAM) device, or a resistive random access memory (RRAM) device. In some embodiments, the first semiconductor device 110 may be a high bandwidth memory (HBM) DRAM device.

The first wiring structure 120 may be arranged on an upper surface of the first semiconductor substrate 100, and the second wiring structure 220 may be arranged on a lower surface of the preliminary semiconductor substrate 200P. The first wiring structure 120 may include a plurality of first wiring layers 121, a plurality of first via plugs 122, and a first wiring insulating layer 123 surrounding the plurality of first wiring layers 121 and the plurality of first via plugs 122. The second wiring structure 220 may include a plurality of second wiring layers 221, a plurality of second via plugs 222, and a second wiring insulating layer 223 surrounding the plurality of second wiring layers 221 and the plurality of second via plugs 222.

For example, each of a first wiring layer 121, a first via plug 122, a second wiring layer 221, and a second via plug 222 may include a metal material, such as W, Cu, Ti, Ta, Ru, Mn, or Co, a nitride or oxide of a metal such as Ti, Ta, Ru, Mn, Co, or W, cobalt tungsten phosphide (CoWP), cobalt tungsten boron (CoWB), cobalt tungsten boron phosphide (CoWBP), or a combination thereof.

For example, each of the first wiring insulating layer 123 and the second wiring insulating layer 223 may include at least one of silicon oxide (SiO), silicon nitride (SiN), silicon oxynitride (SiON), silicon carbonitride (SiCN), silicon oxycarbide (SiOC), a polymer material, and an insulating material having a lower dielectric constant than that of silicon oxide. The polymer material may be benzocyclobutene (BCB), polyimide (PI), polybenzoxazole (PBO), silicone, acrylate, or epoxy. Each of the first wiring insulating layer 123 and the second wiring insulating layer 223 may include, for example, a tetraethyl orthosilicate (TEOS) film. Alternatively, each of the first wiring insulating layer 123 and the second wiring insulating layer 223 may include an ultra-low K (ULK) film having an ultra-low dielectric constant K of about 2.2 to about 2.4. The ULK film may include a SiOC film or a SiCOH film. In some embodiments, each of a lower side portion of the first wiring insulating layer 123 and an upper side portion of the second wiring insulating layer 223, which are respective portions of the first wiring insulating layer 123 and the second wiring insulating layer 223 being in contact with each other, may include silicon carbonitride (SiCN).

The upper semiconductor chip UC may be mounted on the lower semiconductor chip LC such that the first active surface of the first semiconductor substrate 100 faces the second active surface of the preliminary semiconductor substrate 200P, and the first inactive surface of the first semiconductor substrate 100 is opposite to the second inactive surface of the preliminary semiconductor substrate 200P. The first wiring structure 120 and the second wiring structure 220 may be in contact with each other. For example, the first wiring insulating layer 123 of the first wiring structure 120 may be in direct contact with the second wiring insulating layer 223 of the second wiring structure 220.

The upper semiconductor chip UC may include a plurality of through electrodes 230 penetrating the preliminary semiconductor substrate 200P. A through electrode 230 may extend between the first active surface and the first inactive surface of the preliminary semiconductor substrate 200P. At least a portion of the through electrode 230 may have a pillar shape.

The through electrode 230 may include a conductive plug penetrating the preliminary semiconductor substrate 200P and a conductive barrier film surrounding the conductive plug. The conductive plug may have a cylindrical shape, and the conductive barrier film may have a cylindrical shape surrounding a sidewall of the conductive plug. The conductive plug may include Cu, CuSn, CuMg, CuNi, CuZn, CuPd, CuAu, CuRe, CuW, W, or a W alloy, but is not limited thereto. The conductive plug may include, for example, one or more of Al, Au, Be, Bi, Co, Cu, Hf, In, Mn, Mo, Ni, Pb, Pd, Pt, Rh, Re, Ru, Ta, Te, Ti, and W, and may include one or more stacked structures. The conductive barrier film may include, for example, at least one material selected from W, WN, WC, Ti, TiN, Ta, TaN, Ru, Co, Mn, WN, Ni, and NiB, but is not limited thereto.

A via insulating film may be between the preliminary semiconductor substrate 200P and the through electrode 230 to surround the sidewall of the through electrode 230. The via insulating film may include an oxide film, a nitride film, a carbonization film, a polymer, or a combination thereof. The via insulating film may include, for example, an ozone/tetra-ethyl ortho-silicate (O3/TEOS)-based high-aspect-ratio-process (HARP) oxide film.

In FIG. 4B, the upper semiconductor chip UC has a via-middle structure in which one end of the through electrode 230 is connected to the second wiring layer 221 of the second wiring structure 220. However, the present disclosure is not limited thereto, and the upper semiconductor chip UC may be formed in any one of the via-first, via-middle, or via-last structures.

The through electrode 230 may penetrate the preliminary semiconductor substrate 200P from one end to the other end, and the other end of the through electrode 230 may be exposed at the first upper surface 200PA of the preliminary semiconductor substrate 200P. This may mean that the other ends of the plurality of through electrodes 230 may be exposed through a thinning process of the preliminary semiconductor substrate 200P.

A plurality of coupling pads 300 may be between the lower semiconductor chip LC and the upper semiconductor chip UC. The plurality of coupling pads 300 may electrically connect the lower semiconductor chip LC to the upper semiconductor chip UC.

The upper surface of each of the plurality of coupling pads 300 may be connected to the first via plug 122, and the lower surface of each of the plurality of coupling pads 300 may be connected to the second via plug 222. The plurality of coupling pads 300 may be surrounded by the first wiring insulating layer 123 and the second wiring insulating layer 223. A portion of each of the plurality of coupling pads 300 may be buried in the first wiring insulating layer 123, and the remaining portion thereof may be buried in the second wiring insulating layer 223. For example, the remaining portion of an upper side portion of each of the plurality of coupling pads 300 excluding a portion of the upper surface thereof connected to the first via plug 122 may be surrounded by the first wiring insulating layer 123, and the remaining portion of a lower side portion of each of the plurality of coupling pads 300 excluding a portion of the lower surface thereof connected to the second via plug 222 may be surrounded by the second wiring insulating layer 223.

The horizontal width and the horizontal area of the upper semiconductor chip UC may have values less than the horizontal width and the horizontal area of the lower semiconductor chip LC. An edge of the upper semiconductor chip UC may be spaced apart from an edge of the lower semiconductor chip LC and positioned inside the edge of the lower semiconductor chip LC. A first chip vertical thickness CHT1 of the upper semiconductor chip UC may be about 15 μm to about 25 μm. The second wiring structure 220 may have a thickness of about 5 μm to about 10 μm. Similarly, the first wiring structure 120 may have a thickness of about 5 μm to about 10 μm.

A first photoresist thickness PT1 of the first photoresist layer PR1, which is separated from the preliminary semiconductor substrate 200P by a certain distance or more and shows an approximately uniform thickness, may be about 2 μm to about 3 μm. The first photoresist thickness PT1 may be influenced by the amount or density of photoresist applied, and the photoresist may be applied thicker or thinner as necessary.

FIGS. 5A and 5B are enlarged views of an example of a second area B in a first application image SPI1 according to some implementations. In FIG. 5A, the second area B may include a portion of the first gradation area GA1, a portion of the first line application area bundle PL1A, and a portion of the second line application area bundle PL1B. The first gradation area GA1 may include a plurality of points including a non-application point NPP and an application point PP. For example, the first gradation area GA1 of the second area B shown in FIG. 5A may include 5 points in a first direction (X axis direction) and 24 points in a second direction (Y axis direction), which are arranged in a matrix. The application points PP among the plurality of points may be alternately arranged with the non-application points NPP in horizontal and vertical directions. That is, among a total of 120 points, 60 application points PP and 60 non-application points NPP may be distributed in the same ratio.

The inkjet photoresist dispenser described above may distinguish between the application point PP and the non-application point NPP to apply photoresist to the application point PP. For example, the inkjet photoresist dispenser may not apply photoresist to the non-application point NPP of the first gradation area GA1 and may apply photoresist to the application point PP of the first gradation area GA1. Accordingly, the application density and the application interval of photoresist may be appropriately adjusted according to a configuration of the first application image SPI1 including the first gradation area GA1 and the first line application area bundle PL1A.

The first line application area bundle PL1A may include three line application areas. A first line thickness LW1 of each of the three line application areas included in the first line application area bundle PL1A may be less than a first gradation thickness GW1A. For example, the first line thickness LW may be less than half of the first gradation thickness GW1A.

The three line application areas included in the first line application area bundle PL1A may include a plurality of application points PP. For example, one of the three line application areas included in the first line application area bundle PL1A of the second area B shown in FIG. 5A may have 2 points in the first direction (X axis direction) and 24 points in the second direction (Y axis direction), which are arranged in a matrix. A total of 48 points may all be configured as application points PP. Accordingly, when the application density of each of the three line application areas included in the first line application area bundle PL1A is 1, the application density of the first gradation area GA1 may be 0.5.

A first internal line separation distance WL1A, which is a separation distance between the three line application areas included in the first line application area bundle PL1A, may be greater than the first line thickness LW. For example, the first internal line separation distance WL1A may be about 1.5 to about 2 times of the first line thickness LW. Alternatively, the first internal line separation distance WL1A may be equal to the first line thickness LW.

A first outer line area separation distance WL1, which is a separation distance between the first line application area bundle PL1A and the second line application area bundle PL1B, may be greater than the first internal line separation distance WL1A. For example, the first outer line area separation distance WL1 may be about 2 to about 4 times of the first internal line separation distance WL1A.

The size comparisons of the first line thickness LW, the first gradation thickness GW1A, the first outer line area separation distance WL1, and the first internal line separation distance WL1A are examples of application of photoresist. The inventive concept is not limited by the size comparisons.

In FIG. 5B, the second area B may include a portion of the first gradation area GA1, a portion of the first line application area bundle PL1A, and a portion of the second line application area bundle PL1B. However, unlike FIG. 5A, the application density of the first gradation area GA1 may be varied by varying an arrangement of the application points PP and the non-application points NPP of the first gradation area GA1. For example, as in FIG. 5A, the first gradation area GA1 of the second area B may have 5 points in the first direction (X axis direction) and 24 points in the second direction (Y axis direction), which are arranged in a matrix, and the first gradation area GA1 includes 84 application points PP among a total of 120 points, and thus the first gradation area GA1 may have an application density of 84/120. That is, when the application density of each of the three line application areas included in the first line application area bundle PL1A is 1, the first gradation area GA1 may have an application density of about 0.7.

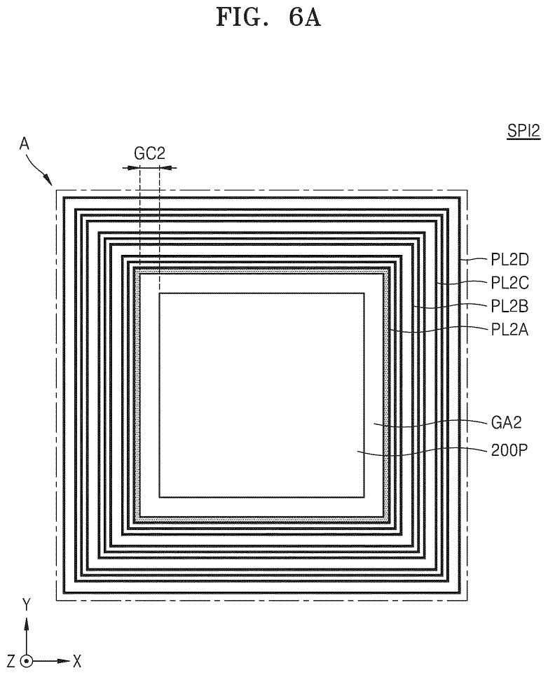

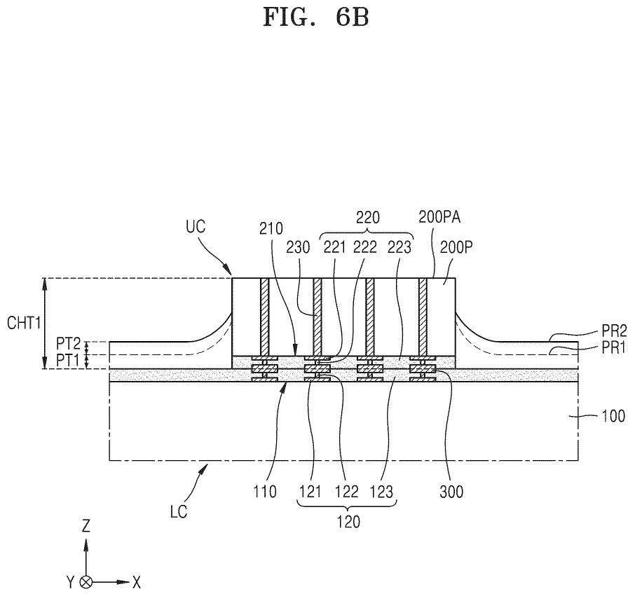

FIG. 6A is a diagram illustrating examples of application images in an example of a selective photoresist application method according to some implementations. FIG. 6B is a cross-sectional view of an example of a semiconductor package, illustrating an example of a semiconductor package manufacturing method using an example of a selective photoresist application method according to some implementations.

In FIGS. 6A and 6B, the application of the first photoresist layer PR1 according to the first application image SPI1 may be completed, and the application of a second photoresist layer PR2 according to a second application image SPI2 may be performed. The second application image SPI2 may include a second gradation application area GA2 and a line application area, similarly to the first application image SPI1. The line application area may include, for example, a first line application area bundle PL2A, a second line application area bundle PL2B, a third line application area bundle PL2C, and a fourth line application area bundle PL2D.

In the second application image SPI2, each of the first line application area bundle PL2A, the second line application area bundle PL2B, the third line application area bundle PL2C, and the fourth line application area bundle PL2D may have one or more line application areas. For example, each of the first line application area bundle PL2A, the second line application area bundle PL2B, and the third line application area bundle PL2C may have three line application areas, and the fourth line application area bundle PL2D may have one line application area.

The three line application areas included in the first line application area bundle PL2A may be arranged to be spaced apart from each other at a distance. As shown in FIG. 6A, the line application areas may be arranged to be spaced apart from each other with the preliminary semiconductor substrate 200P as the center. Similarly, the three line application areas included in the second line application area bundle PL2B may be arranged to be spaced apart from each other with the preliminary semiconductor substrate 200P as the center, and the three line application areas included in the third line application area bundle PL2C may be arranged to be spaced apart from each other with the preliminary semiconductor substrate 200P as the center. For example, when the preliminary semiconductor substrate 200P has a rectangular shape, each of the line application areas may have a rectangular shape with an enlarged outer edge of the preliminary semiconductor substrate 200P.

The second application image SPI2 may include the second gradation application area GA2 between the first line application area bundle PL2A and the preliminary semiconductor substrate 200P. The second gradation application area GA2 may have a low photoresist application density, unlike the first line application area bundle PL2A.

The second gradation application area GA2 may be spaced apart from the outer edge of the preliminary semiconductor substrate 200P. In addition, the second gradation application area GA2 may surround the outer edge of the preliminary semiconductor substrate 200P. The second gradation application area GA2 may be spaced apart from the outer edge of the preliminary semiconductor substrate 200P at a uniform distance. The second gradation application area GA2 may be spaced apart from the outer edge of the preliminary semiconductor substrate 200P by a second gap GC2. The second gap GC2, which is a separation distance between the outer edge of the preliminary semiconductor substrate 200P and the second gradation application area GA2, in the second application image SPI2 may be greater than the first gap GC1, which is a separation distance between the outer edge of the preliminary semiconductor substrate 200P and the first gradation area GA1, in the first application image SPI1. For example, as described above, the first gap GC1 may be about 50 μm to about 200 μm and the second gap GC2 may be about 70 μm to about 250 μm.

In FIG. 6B, photoresist may be applied on the first photoresist layer PR1 according to the second application image SPI2, and the second photoresist layer PR2 may be formed.

A second photoresist thickness PT2 of the second photoresist layer PR2, which is separated from the preliminary semiconductor substrate 200P by a certain distance or more and shows an approximately uniform thickness, may be about 2 μm to about 3 μm. This is a value generally similar to the first photoresist thickness PT1. However, because the thickness of the first photoresist layer PR1 in a vertical direction at a position adjacent to the preliminary semiconductor substrate 200P is greater than the first photoresist thickness PT1, when the same application image as the first application image SPI1 used for application of the first photoresist layer PR1 is used when applying the second photoresist layer PR2, photoresist may be applied on the first upper surface 200PA of the preliminary semiconductor substrate 200P. As described above, this is because photoresist tends to adhere to the first semiconductor substrate 100.

Photoresist may be applied according to the second application image SPI2 in which the second gap GC2 is set to be greater than the first gap GC1, and the second photoresist layer PR2 may be formed such that the photoresist is not applied on the first upper surface 200PA of the preliminary semiconductor substrate 200P. That is, when forming the second photoresist layer PR2, an area to be applied with photoresist is at a point further away from the preliminary semiconductor substrate 200P, and thus the photoresist is not applied on the first upper surface 200PA of the preliminary semiconductor substrate 200P.

When forming photoresist through spin coating, which is a general photoresist formation process, there is a high possibility that voids may be generated at photoresist adjacent to the preliminary semiconductor substrate 200P due to the characteristics of application of photoresist simultaneously with the rotation of a wafer.

In the case where the voids are generated at the photoresist in contact with the preliminary semiconductor substrate 200P, the voids may be exposed when the preliminary semiconductor substrate 200P is recessed by etching, and a side surface of the preliminary semiconductor substrate 200P, which is exposed by the voids, may also be etched through the voids. The shape of the voids is indiscriminate, and when forming photoresist through spin coating, which is a general photoresist formation process, the yield of semiconductor packages may be reduced when etching occurs on a side surface of the preliminary semiconductor substrate 200P.

According to the selective photoresist application method 10, photoresist may be applied by an inkjet photoresist dispenser according to a plurality of application images. The formation of voids at photoresist formed adjacent to the preliminary semiconductor substrate 200P may be prevented or reduced by adhering photoresist to the preliminary semiconductor substrate 200P by using the property of the photoresist near the preliminary semiconductor substrate 200P, which adheres to the preliminary semiconductor substrate 200P. That is, the yield of semiconductor packages may be improved by the selective photoresist application method 10 according to an embodiment.

In addition, the amount of photoresist to be applied is set not to be applied on the first upper surface 200PA of the preliminary semiconductor substrate 200P according to a plurality of application images by using the selective photoresist application method 10, and thus the number of processes generally performed may be reduced. This will be described below.

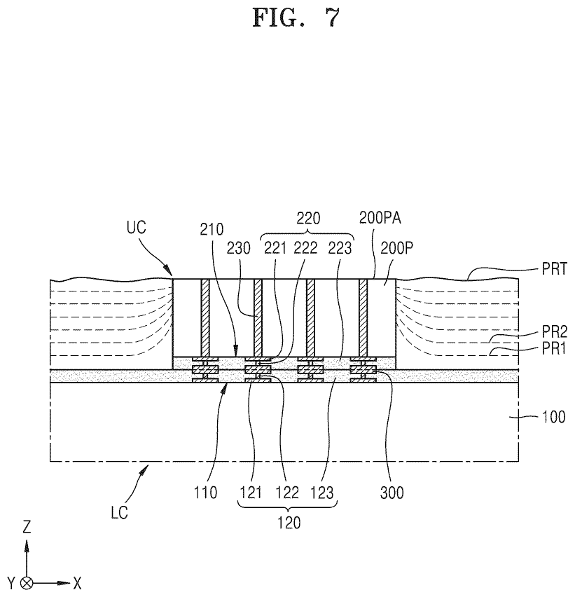

FIGS. 7 to 9 are cross-sectional views illustrating an example of a semiconductor package manufacturing method using an example of a selective photoresist application method according to some implementations. In FIG. 7, a plurality of photoresist layers may be formed by a plurality of application images. That is, the plurality of photoresist layers may be formed by the plurality of application images similar to the first application image SPI1 and the second application image SPI2 described above. For example, the formation of photoresist may be performed seven times by the plurality of application images including seven application images, as shown in FIG. 7.

The vertical level of a photoresist uppermost surface PRT, which is the uppermost surface of the plurality of photoresist layers, may be formed to be approximately the same as the vertical level of the first upper surface 200PA of the preliminary semiconductor substrate 200P. In addition, the outer edge of the first upper surface 200PA of the preliminary semiconductor substrate 200P and the photoresist uppermost surface PRT may extend. That is, the photoresist overflows and is not formed on the first upper surface 200PA of the preliminary semiconductor substrate 200P. This is possible because the application density and amount of photoresist are adjusted by the plurality of application images.

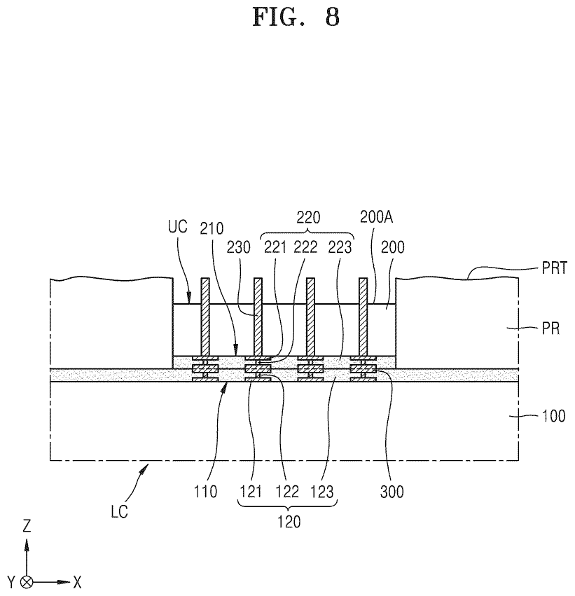

In FIG. 8, after the formation of photoresist PR is completed by light irradiation or the like, the preliminary semiconductor substrate 200P may be etched. The preliminary semiconductor substrate 200P may be etched to form a second semiconductor substrate 200, and a plurality of through electrodes 230 may protrude by penetrating a second upper surface 200A of the second semiconductor substrate 200.

In a photoresist process using spin coating, in which photoresist is also formed on the first upper surface 200PA of the preliminary semiconductor substrate 200P, when photoresist is formed on the first upper surface 200PA of the preliminary semiconductor substrate 200P, a separate process of removing the photoresist formed on the first upper surface 200PA of the preliminary semiconductor substrate 200P is required to etch the preliminary semiconductor substrate 200P. However, in the semiconductor package manufacturing method 20 using the selective photoresist application method 10 according to some implementations, because photoresist is not formed on the first upper surface 200PA of the preliminary semiconductor substrate 200P, after the formation of the photoresist is completed, the preliminary semiconductor substrate 200P may be etched without an additional photoresist removal process. Accordingly, because the number of processes of manufacturing a semiconductor package is reduced, the manufacturing efficiency of semiconductor packages may be improved by the semiconductor package manufacturing method 20.

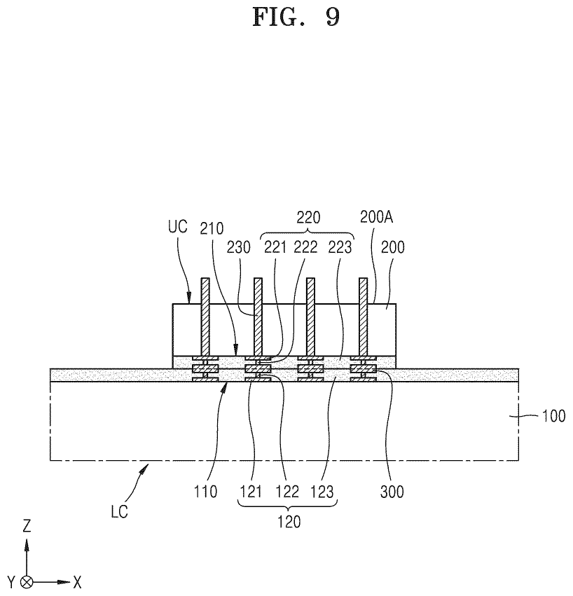

In FIG. 9, the photoresist PR surrounding a side surface of the preliminary semiconductor substrate 200P may be removed. A semiconductor package may be completed by performing an additional process on the semiconductor structure including the upper semiconductor chip UC and the lower semiconductor chip LC of FIG. 9.

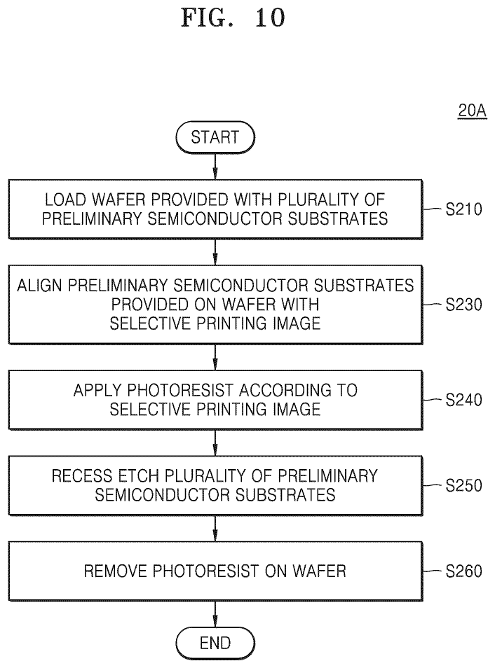

FIG. 10 is a flowchart illustrating an example of a semiconductor package manufacturing method using an example of a selective photoresist application method according to some implementations. In FIG. 10, the semiconductor package manufacturing method 20A using the selective photoresist application method may include operation S210 of preparing a wafer structure with a plurality of preliminary semiconductor substrates provided on the upper surface thereof, operation S230 of aligning the plurality of preliminary semiconductor substrates with a selective printing image, operation S240 of applying photoresist on the wafer structure according to the selective printing image, operation S250 of recess etching the plurality of preliminary semiconductor substrates, and operation S260 of removing the photoresist on the wafer structure.

According to the selective photoresist application method, photoresist is not applied on the first upper surface 200PA of the preliminary semiconductor substrate 200P. Accordingly, the preliminary semiconductor substrate 200P may not be thinned. That is, in operation S250 of recess etching the plurality of preliminary semiconductor substrates, the preliminary semiconductor substrate 200P may be etched. Accordingly, because the number of processes of manufacturing a semiconductor package is reduced, the manufacturing efficiency of semiconductor packages may be improved by the semiconductor package manufacturing method 20A.

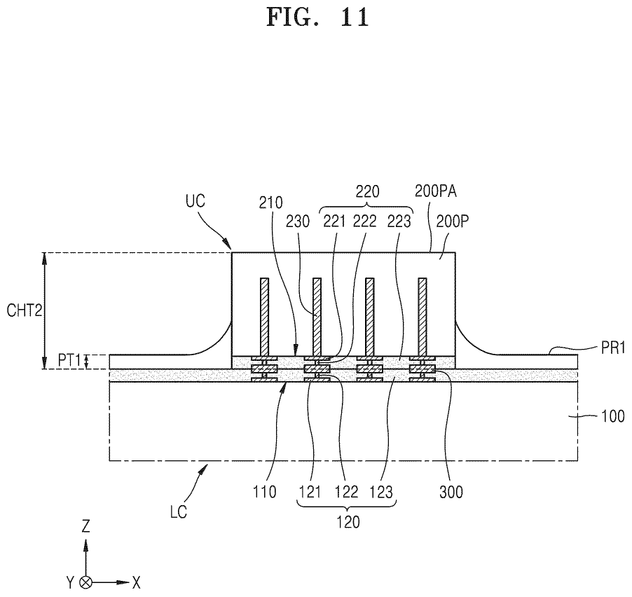

FIGS. 11 to 14 are cross-sectional views illustrating the semiconductor package manufacturing method 20A using the selective photoresist application method 10 according to some implementations. In FIG. 11, because the preliminary semiconductor substrate 200P has not been thinned, the other end of each of the plurality of through electrodes 230 may not be exposed on the first upper surface 200PA of the preliminary semiconductor substrate 200P. Accordingly, a second chip vertical thickness CHT2 of the upper semiconductor chip UC may be greater than the first chip vertical thickness CHT1 (as shown in FIG. 4B), and the second chip vertical thickness CHT2 of the upper semiconductor chip UC may be about 25 μm to about 35 μm.

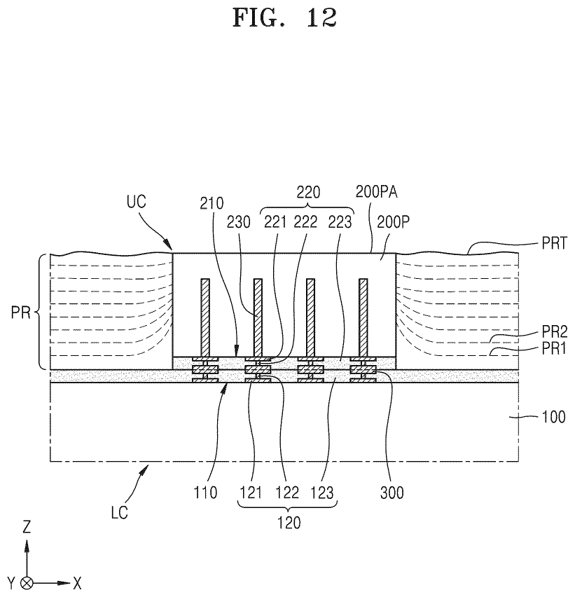

In FIG. 12, because the second chip vertical thickness CHT2 is greater than the first chip vertical thickness CHT1, unlike in FIG. 7, a plurality of photoresist layers may be formed by more application images. For example, the formation of photoresist may be performed nine times by the plurality of application images including nine application images, as shown in FIG. 12.

The vertical level of the photoresist uppermost surface PRT, which is the uppermost surface of the plurality of photoresist layers, may be formed to be approximately the same as the vertical level of the first upper surface 200PA of the preliminary semiconductor substrate 200P. In addition, the outer edge of the first upper surface 200PA of the preliminary semiconductor substrate 200P and the photoresist uppermost surface PRT may extend. That is, the photoresist overflows and is not formed on the first upper surface 200PA of the preliminary semiconductor substrate 200P. This is possible because the application density and amount of photoresist are adjusted by the plurality of application images.

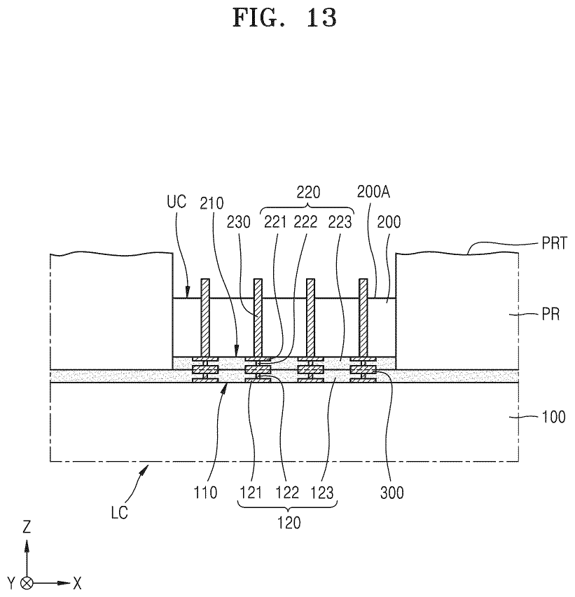

In FIG. 13, after the formation of photoresist PR is completed by light irradiation or the like, the preliminary semiconductor substrate 200P may be etched. The preliminary semiconductor substrate 200P may be etched to form the second semiconductor substrate 200, and the plurality of through electrodes 230 may protrude by penetrating the second upper surface 200A of the second semiconductor substrate 200.

In the semiconductor package manufacturing method 20A, using the selective photoresist application method 10 according to some implementations, because photoresist is not formed on the first upper surface 200PA of the preliminary semiconductor substrate 200P, after the formation of the photoresist is completed, the preliminary semiconductor substrate 200P may be etched without an additional photoresist removal process. Accordingly, because the number of processes of manufacturing a semiconductor package is reduced, the manufacturing efficiency of semiconductor packages may be improved by the semiconductor package manufacturing method 20A.

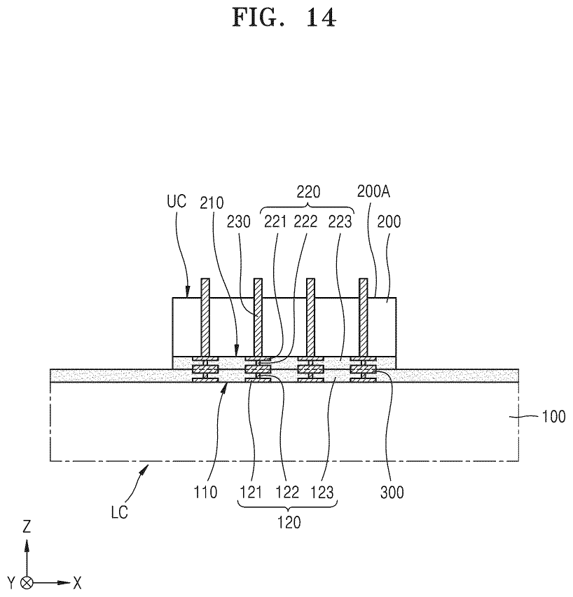

In FIG. 14, the photoresist PR surrounding a side surface of the preliminary semiconductor substrate 200P may be removed. A semiconductor package may be completed by performing an additional process on the semiconductor structure including the upper semiconductor chip UC and the lower semiconductor chip LC of FIG. 14.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. A selective photoresist application method comprising:
measuring positions, sizes, and heights of chips provided on a wafer;
generating a position image of the chips;
preparing a plurality of application images for application of photoresist based on the position image; and
sequentially applying and stacking the photoresist, from a dispenser, on the wafer according to the plurality of application images to form a stacked photoresist,
wherein each application image of the plurality of application images comprises a gradation application area corresponding to a respective chip location and a plurality of line application areas corresponding to the respective chip location,
wherein the gradation application area is defined as an area having an application density of the photoresist of less than 1, the application density comprising a ratio of a first area comprising a first group of application points of a plurality of application points of the photoresist to a second area comprising a total of the plurality of application points of the photoresist, and
wherein each line application area of the plurality of line application areas is defined as an area having an application density of the photoresist of 1.

2. The selective photoresist application method of claim 1,
wherein an uppermost surface of the stacked photoresist extends to outer edges of upper surfaces of the chips, and
wherein the upper surfaces of the chips are exposed from the stack of photoresist.

3. The selective photoresist application method of claim 2,
wherein the gradation application area is spaced apart from outer edges of each of the chips, and
wherein the gradation application area surrounds each of the chips.

4. The selective photoresist application method of claim 3, wherein the gradation application area is closer to the chips than the plurality of line application areas.

5. The selective photoresist application method of claim 4,
wherein the plurality of application images comprise a first application image and a second application image, and
wherein a second separation distance between a second gradation application area of the second application image and the corresponding chips is greater than a first separation distance between a first gradation application area of the first application image and the corresponding chips.

6. The selective photoresist application method of claim 5, wherein one line application area among the plurality of line application areas is arranged outside the gradation application area and extends with the gradation application area.

7. The selective photoresist application method of claim 5, wherein the plurality of application images comprise at least four application images.

8. The selective photoresist application method of claim 7,
wherein the gradation application area comprises a plurality of points,
wherein the plurality of points comprise non-application points and application points, and
wherein the application density, which is a ratio of an area of the application points to an area of the plurality of points, is about 0.3 to about 0.8.

9. The selective photoresist application method of claim 7,
wherein the plurality of line application areas comprise a first line application area bundle and a second line application area bundle,
wherein the first line application area bundle comprises two or more line application areas, and the second line application area bundle comprises two or more line application areas,
wherein a first internal line separation distance between the two or more line application areas of the first line application area bundle is less than a first outer line separation distance between the first line application area bundle and the second line application area bundle, and
wherein the first outer line separation distance is about 2 to about 4 times greater than the first internal line separation distance.

10. The selective photoresist application method of claim 9, wherein the first internal line separation distance is equal to a second internal separation distance between the two or more line application areas of the second line application area bundle.

11. The selective photoresist application method of claim 1, wherein a plurality of coupling pads are provided between the wafer and the chips.

12. The selective photoresist application method of claim 1, further comprising, after the applying the photoresist on the wafer, determining an application state of the photoresist.

13. A selective photoresist application method comprising:
preparing a wafer structure comprising a plurality of first semiconductor chips, each semiconductor chip of the plurality of first semiconductor chips comprises a first semiconductor substrate, a first wiring structure arranged on the first semiconductor substrate, and a plurality of first front surface connection pads at least partially buried in the first wiring structure;
adhering, on the wafer structure, an upper semiconductor chip comprising a preliminary semiconductor substrate, a plurality of through electrodes buried in the preliminary semiconductor substrate, a second wiring structure arranged on the preliminary semiconductor substrate, and a plurality of second front surface connection pads arranged on the second wiring structure, such that the plurality of first front surface connection pads and the plurality of second front surface connection pads are aligned to each other;
forming a plurality of coupling pads by coupling the plurality of first front surface connection pads to the plurality of second front surface connection pads;
aligning the wafer structure on which the upper semiconductor chip is arranged with a plurality of application images for application of photoresist;
sequentially applying and stacking the photoresist on the wafer structure according to the plurality of application images to form a stacked photoresist; and
forming a second semiconductor substrate by removing a portion of the upper semiconductor chip to expose the plurality of through electrodes,
wherein each application image of the plurality of application images comprises a gradation application area corresponding to a location of the upper semiconductor chip and a plurality of line application areas corresponding to location of the upper semiconductor chip,
wherein the gradation application area is defined as an area having an application density of the photoresist of less than 1, the application density comprising a ratio of a first area comprising a first group of application points of a plurality of application points of the photoresist to a second area comprising a total of the plurality of application points of the photoresist and
wherein each of the plurality of line application areas is defined as an area having an application density of the photoresist of 1.

14. The selective photoresist application method of claim 13,
wherein, after the applying and stacking of the photoresist, an uppermost surface of the stacked photoresist is in contact with an outer edge of an upper surface of the upper semiconductor chip, and
wherein the upper surface of the upper semiconductor chip is exposed from the stacked photoresist.

15. The selective photoresist application method of claim 14, further comprising, after the forming of the plurality of coupling pads, thinning the upper semiconductor chip.

16. The selective photoresist application method of claim 14,
wherein the gradation application area is spaced apart from the outer edge of the upper semiconductor chip,
wherein the gradation application area surrounds the upper semiconductor chip, and
wherein the gradation application area is closer to the upper semiconductor chip than the plurality of line application areas.

17. The selective photoresist application method of claim 16,
wherein the plurality of application images comprise a first application image and a second application image, and
wherein a second separation distance between a second gradation application area of the second application image and the corresponding upper semiconductor chip, is greater than a first separation distance between a first gradation application area of the first application image and the corresponding upper semiconductor chip.

18. The selective photoresist application method of claim 17,
wherein one line application area among the plurality of line application areas is arranged outside the gradation application area to extend with the gradation application area,
wherein the gradation application area comprises a plurality of points,
wherein the plurality of points comprise a plurality of non-application points and the plurality of application points, and
wherein the application density of the gradation application area is about 0.3 to about 0.9.

19. The selective photoresist application method of claim 17, wherein the plurality of line application areas comprise a first line application area bundle and a second line application area bundle, the first line application area bundle comprises two or more line application areas, the second line application area bundle comprises two or more line application areas,
wherein a first internal line separation distance between the two or more line application areas of the first line application area bundle is less than a first outer line separation distance between the first line application area bundle and the second line application area bundle, and
wherein the first outer line separation distance is about 2 to about 4 times greater than the first internal line separation distance.

20. A selective photoresist application method comprising:
measuring a position, size, and height of a preliminary semiconductor substrate provided on a wafer;
generating a position image of the preliminary semiconductor substrate;
preparing a plurality of application images for application of photoresist based on the position image; and
sequentially stacking and applying the photoresist, from a dispenser, on the wafer according to the plurality of application images to form a stacked photoresist,
wherein each of application image of the plurality of application images comprises a gradation application area corresponding to a respective location of the preliminary semiconductor substrate and a plurality of line application areas corresponding to the respective location of the preliminary semiconductor substrate,
wherein the gradation application area is spaced apart from an outer edge of the preliminary semiconductor substrate corresponding to the gradation application area,
wherein the gradation application area surrounds the corresponding preliminary semiconductor substrate,
wherein the gradation application area is closer to the preliminary semiconductor substrate than the plurality of line application areas,
wherein the plurality of application images comprise at least four application images and comprise a first application image and a second application image,
wherein a second separation distance between a second gradation application area of the second application image and the corresponding location of the preliminary semiconductor substrate is greater than a first separation distance between a first gradation application area of the first application image and the corresponding location of the preliminary semiconductor substrate,
wherein one line application area among the plurality of line application areas is arranged outside the gradation application area to extend with the gradation application area,
wherein the gradation application area comprises a plurality of points,
wherein the plurality of points comprise a plurality of non-application points and a plurality of application points,
wherein the gradation application area has an application density of the photoresist of about 0.3 to about 0.9, each of the plurality of line application areas has an application density of the photoresist of 1, the application density comprises a ratio of a first area comprising a first group of application points of the plurality of application points of the photoresist to a second area comprising a total of the plurality of points of the photoresist,
wherein the plurality of line application areas comprise a first line application area bundle and a second line application area bundle,
wherein the first line application area bundle comprises two or more line application areas, and the second line application area bundle comprises two or more line application areas,
wherein a first internal line separation distance between the two or more line application areas of the first line application area bundle is less than a first outer line separation distance between the first line application area bundle and the second line application area bundle,
wherein the first outer line separation distance is greater than the first internal line separation distance by about 2 to about 4 times,
wherein an uppermost surface of the stacked photoresist is in contact with an outer edge of an upper surface of the preliminary semiconductor substrate,
wherein the upper surface of the preliminary semiconductor substrate is exposed from the stack of photoresist, and
wherein a plurality of coupling pads are provided between the wafer and the preliminary semiconductor substrate.
